(19) United States
(12) Patent Application Publication
(10) Pub. No.: US 2010/0193835 A1
(43) Pub. Date: Aug. 5, 2010

(54) Trench insulated gate bipolar transistor (GBT) with improved emitter-base contacts and metal schemes

(75) Inventor: Fwu-Iuan Hshieh, Saratoga, CA (US)

Correspondence Address: BO-IN LIN, 13445 MANDOLI DRIVE, LOS ALTOS HILLS, CA, 94022, US

(73) Assignee: Force-MOS Technology Corporation

(21) Appl. No.: 12/322,656

(22) Filed: Feb. 5, 2009

(51) Int. Cl. H01L 29/739; H01L 21/331

(52) U.S. Cl. 257/139; 438/138; 257/E29.197; 257/E21.385

(57) ABSTRACT

A trench insulation gate bipolar transistor (IGBT) power device includes a plurality of trench gates surrounded by emitter regions of a first conductivity type near a top surface of a semiconductor substrate encompassed in base regions of a second conductivity type and a collector layer disposed at a bottom surface of the semiconductor substrate. The trench IGBT power device further includes an insulation layer covering over the top surface over the trench gate and the emitter regions having emitter-base contact trenches opened therethrough between the trench gates and extending to the base regions and an emitter-base contact dopant region disposed in the base region of the second conductivity type surrounding a lower region of the contact trenches. The emitter-base contact dopant region is disposed at a distance away from a channel near the trench gates for reducing an emitter-base resistance without increasing a gate-emitter threshold voltage.

### BACKGROUND OF THE INVENTION

1. Field of the Invention

The invention relates generally to a device configuration and method of manufacturing an insulated gate bipolar transistor (IGBT). More particularly, this invention relates to an improved IGBT device configuration and manufacturing method for a trench IGBT that has improved emitter-base contacts and metal schemes.

2. Description of the Relevant Art

As a key component in the power electronic systems, the semiconductor power devices are commonly implemented in the power electronic systems such as the power systems for the hybrid, electric or fuel cells vehicles. Recently, there are increasing demands for high performance semiconductor power devices. Particularly, there are increasing demands for high performance high voltage semiconductor power devices such as the insulated gate bipolar transistor (IGBT) devices. However, conventional high voltage semiconductor power devices such as the insulated gate bipolar transistor (IGBT) devices are still confronted with the technical difficulties caused by an increased collector-emitter saturation voltage. The increase of collector-emitter saturation voltage becomes even more pronounced when the IGBT is manufactured with further miniaturized size to increase the cell density of semiconductor power device.

Hattori et al. disclose in U.S. Pat. No. 6,894,347 a semiconductor IGBT power device as shown in FIG. 1A. The IGBT device includes an n+ type buffer layer 41, an n-type base layer 42 having a high resistivity, a p+ base layer 51 having a high impurity concentration and a p-type base layer 43 having a low impurity concentration are formed in the order mentioned on one surface region of a p+ collector layer 40. Also, an n+ emitter layer 44 selectively formed in a part of the surface region of the p base layer 43. A trench 45 is formed to extend downward from the surface of the emitter layer to reach the n-type base layer 42 through the emitter layer 44, the p-type base layer 43 and the p+ base layer 51. A gate electrode 47 (trench-gate electrode), which is covered with a gate insulating film 46, is buried in the trench 45. Incidentally, the emitter layer 44 is formed to have, for example, a striped pattern consisting of a plurality of columns as viewed from above, and the trench 45 is formed in a middle region of adjacent the emitter layers 44. An emitter electrode 48 formed of an aluminum wiring, which is electrically insulated from the gate electrode 47 and permits the short-circuiting between the emitter layer 44 and the p-type base layer 43, is formed to cover the emitter layer 44 and the p-type base layer 43. An insulating film 49 is deposited on the p-type base layer 43 and the trench-gate electrode 47, and the emitter electrode 48 is formed to be in contact with a part of the emitter layer 44 and with a part of the p-type base layer 43 via a contact hole formed in the insulating film 49 for the lead of the emitter-base. A collector electrode 50 is formed on the back surface of the p+ collector layer 40. A trench 52 extending through a p-type base layer 43 in a manner to have the bottom thereof positioned on the surface of or within a p+ base layer 51 is formed between the adjacent trenches 45. The emitter electrode 48 is buried in the trench 52.

The IGBT device disclosed in U.S. Pat. No. 6,894,347 as that shown in FIG. 1A is provided to improve the short circuit withstand capability while maintaining low on-voltage. However, the device as shown in FIG. 1A has a disadvantage that the P+base 51 touches the channel region thus causes a high gate-emitter threshold voltage that in turn increases the collector-emitter saturation voltage.

Huang et al. disclose in U.S. Pat. No. 6,437,399 a semiconductor power device as shown in FIG. 1B. The IGBT device is a trench IGBT with a trench gate 26. The trench IGBT is formed with an emitter metal 36 extended into a trench opened through a BPSG layer 30 and opened into a depth greater than the P-baser region 14 and extended into a P+ region 35 doped in a N-buffer layer 10 supported on a P-substrate. The IGBT disclosed by Huang has a disadvantage due to the P+ base region 35 deeper than the base region 14 thus causing a high JFET resistance between two adjacent contact trenches. The higher JFET resistance further causes an increase in the collector-emitter saturation voltage.

Therefore, a need still exists in the art of power semiconductor device design and manufacture to provide new manufacturing method and device configuration in forming the semiconductor power devices such that the above discussed problems and limitations can be resolved.

### SUMMARY OF THE PRESENT INVENTION

It is therefore an aspect of the present invention to provide a new and improved insulation gate bipolar transistor (IGBT) power device by forming emitter-base contact dopant regions underneath an emitter-dopant contact trenches. The emitter-base contact dopant regions are formed at a distance away from the channels near the trench gate. The emitter-base dopant contact regions reduce the base contact resistance. The emitter-base contact dopant regions are further formed at a distance away from the channel regions. The emitter-base contact dopant regions can therefore enhance latch-up immunity capability of the IGBT device without increase the gate-emitter threshold voltage.

Another aspect of this invention is to provide a new and improved insulation gate bipolar transistor (IGBT) power device by forming emitter-base contact dopant regions underneath an emitter-dopant contact trenches. The emitter-base contact trenches are formed with vertical sidewalls in the emitter regions and with tapered sidewalls merging toward a bottom surface of the contact trenches. The tapered sidewalls thus allow a dopant implant with zero tilt angle relative to the vertical direction for directly implanting the dopant ions into the regions below the contact trenches and through the tapered sidewalls into the base regions near the bottom of the emitter-base contact trenches. The emitter-base contact dopant regions surrounding the bottom portions of the emitter-base contact trenches are formed with more uniformed dopant ions distribution thus significantly reduce the contact regions and further improves the latch-up immunity capability without unduly increase the emitter-gate threshold voltage.

Briefly in a preferred embodiment, this invention discloses a trench insulation gate bipolar transistor (IGBT) power device includes a plurality of trench gates surrounded by emitter regions of a first conductivity type near a top surface of a semiconductor substrate encompassed in base regions of a second conductivity type. The trench semiconductor power device further includes an epitaxial layer of a first conductivity type includes a layer below the base region of the second conductivity and a buffer layer with a higher concentration of dopant ions of the first conductivity than the base layer of the first conductivity. The IGBT power device further includes a collector layer of the second conductivity type disposed below the buffer layer and an insulation layer covering over the top surface over the trench gate and the emitter regions having emitter-base contact trenches opened therethrough between the trench gates and extending to the base regions of the second conductivity wherein each of the emitter-base contact trenches filled with a metal plug for electrically contacting the emitter regions and the base regions. The semiconductor power device further includes an emitter-base contact dopant region disposed in the base region of the second conductivity type surrounding a lower region of the contact trenches and doped with a higher concentration of dopant ions of the second conductivity type than the base region of the second conductivity type wherein the emitter-base contact dopant region is disposed at a distance away from a channel near the trench gates for reducing an emitter-base resistance without increasing a gate-emitter threshold voltage. In an exemplary embodiment, the emitter-base contact dopant region has a dopant concentration ranging from 1E18 to 1E20/cm³ higher than a dopant concentration of the base region of the second conductivity type. In another exemplary embodiment, the emitter-base contact dopant region is disposed at a distance of about 0.2 μm from the channel of the IGBT near the trench gates. In another exemplary embodiment, the emitter-base contact trenches further includes a barrier layer disposed around sidewalls and a bottom surface of the emitter-base contact trenches surrounding the metal plug filling in the emitter-base contact trenches. In another exemplary embodiment, the metal plug filled in the emitter-base contact trenches further includes a tungsten plug for electrically contacting the emitter regions and the base regions. In another exemplary embodiment, the emitter-base contact trenches further includes a barrier layer composed of Ti/TiN disposed around sidewalls and a bottom surface of the emitter-base contact trenches surrounding the metal plug filling in the emitter-base contact trenches. In another exemplary embodiment, the emitter-base contact trenches further includes a barrier layer composed of Co—TiN disposed around sidewalls and a bottom surface of the emitter-base contact trenches surrounding the metal plug filling in the emitter-base contact trenches. In another exemplary embodiment, the first conductivity type is an N-type conductivity type and the second conductivity type is a P-type conductivity type. In another exemplary embodiment, the first conductivity type is a P-type conductivity type and the second conductivity type is an N-type conductivity type. In another exemplary embodiment, the emitter-base contact trenches further includes sidewalls having substantially a straight-line cross section profile. In another exemplary embodiment, the emitter-base contact trenches further includes sidewalls having substantially a straight-line cross section profile along substantially a vertical direction relative to the top surface of the semiconductor substrate. In another exemplary embodiment, the emitter-base contact trenches further includes sidewalls having substantially a straight-line cross section profile along substantially angularly sloped direction relative to the top surface of the semiconductor substrate. In another exemplary embodiment, the emitter-base contact trenches further includes sidewalls having a vertical line profile on an upper portion of the contact trenches along substantially a direction perpendicular relation to the top surface of the semiconductor substrate and a slope line profile angularly intersecting with the vertical line profile and converging to a flat bottom surface of the contact trenches on a lower portion of the contact trenches. In another exemplary embodiment, the emitter-base contact trenches further includes sidewalls having a vertical line profile on an upper portion of the contact trenches along substantially a direction perpendicular relation to the top surface of the semiconductor substrate in the emitter regions and a slope line profile angularly intersecting with the vertical line profile and converging to a flat bottom surface of the contact trenches on a lower portion of the contact trenches in the base region of the second conductivity type. In another exemplary embodiment, the emitter-base contact trenches further includes an widened top opening in the insulation layer having a width greater than a width between sidewalls of the trenches in the emitter regions for providing a greater top surface area than a cross sectional area of the trenches opened in the emitter region and base region in the semiconductor substrate. In another exemplary embodiment, the IGBT power device further includes a metal layer disposed on top of the insulation layer and filling in the emitter-base contact trenches constituting the metal plug filled in the emitter-base contact trenches for electrically contacting the emitter regions and the base regions.

This invention further discloses a method for manufacturing a trench IGBT power device that includes steps of forming trench gates and emitter and base regions in a semiconductor substrate. The method further includes a step of covering a top surface of the semiconductor substrate with an insulation layer and applying a mask to etch and open a plurality of emitter-base contact trenches through the insulation layer into the base regions. The etch process further includes a process of applying a single etch process to open substantially vertical trench in the emitter region and etching a bottom portion in the base region with a tapered angle with sloped sidewalls merging to a bottom surface of the contact trenches. In an exemplary embodiment, the method further includes a step of applying a zero degree dopant implant into the emitter-base contact trenches for forming an emitter-base contact dopant region in the base regions surrounding the bottom portion of the emitter-base contact trenches.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A to 1B are cross sectional views of different conventional trenched IGBT power devices.

FIGS. 2A to 5D are cross sectional view of alternate embodiments of the present invention of a trenched IGBT devices implemented with emitter-base trench contacts.

FIG. 6 is cross sectional view for illustrating a processing step to open emitter-base contact trenches with tapered sidewalls at a bottom portion of the contact trenches formed with vertical sidewalls on the top portions.

### DETAILED DESCRIPTION OF THE METHOD

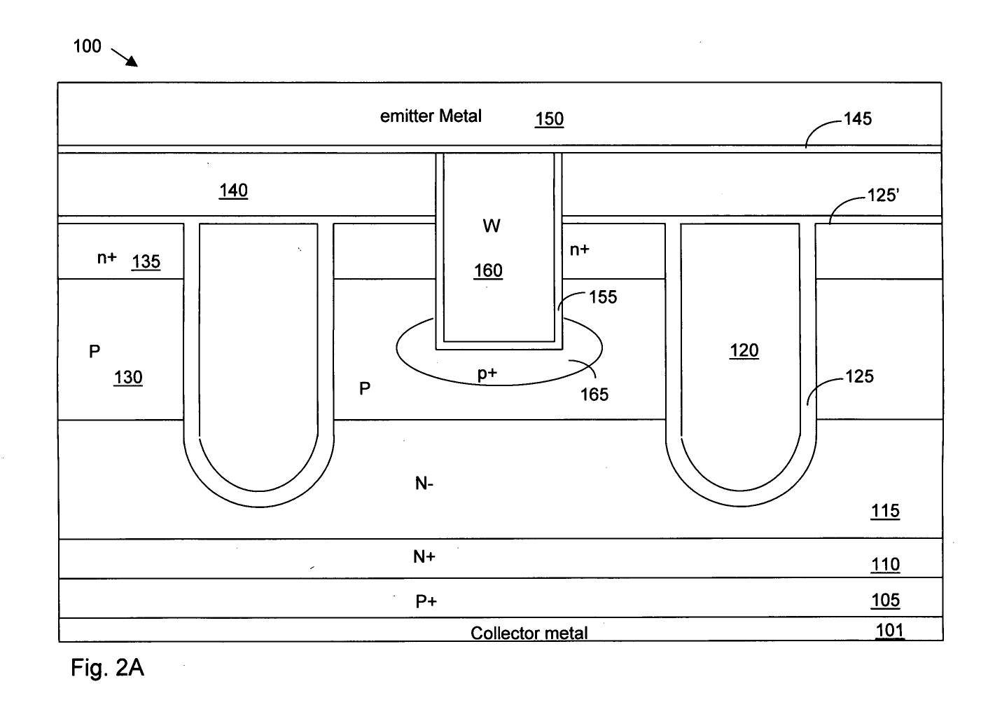

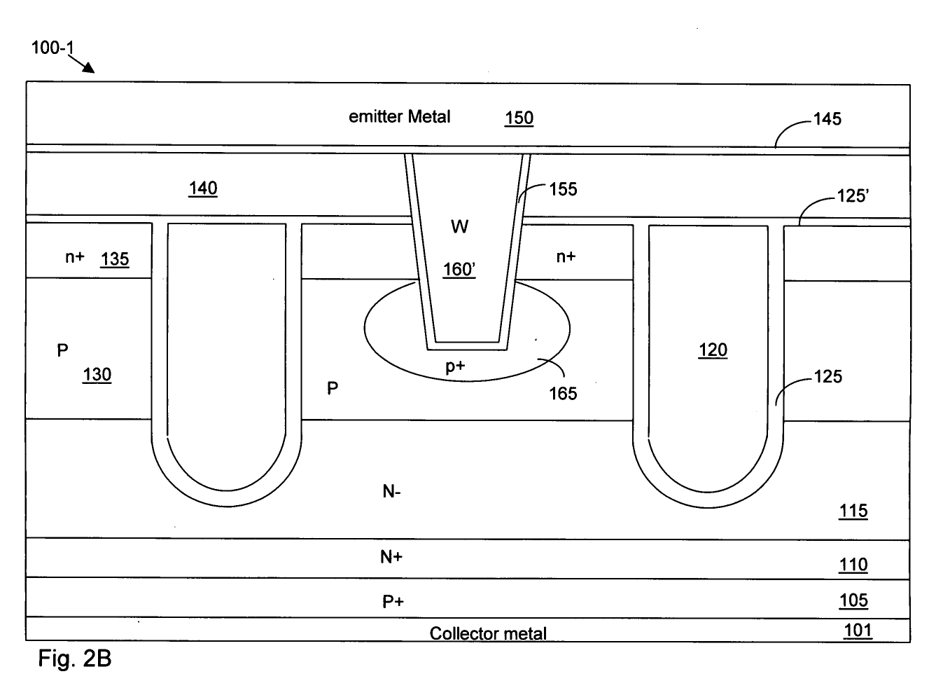

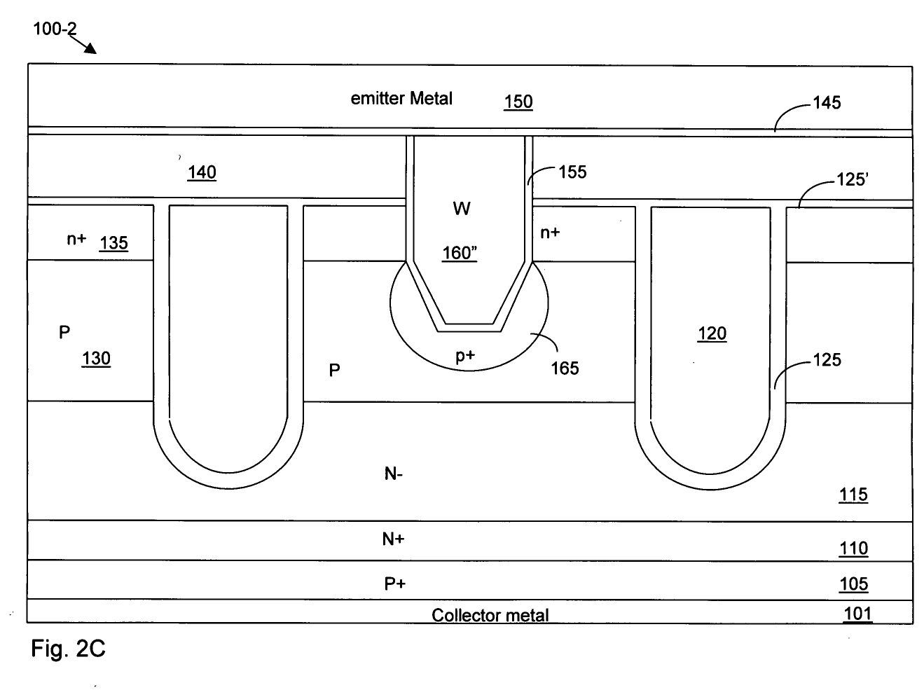

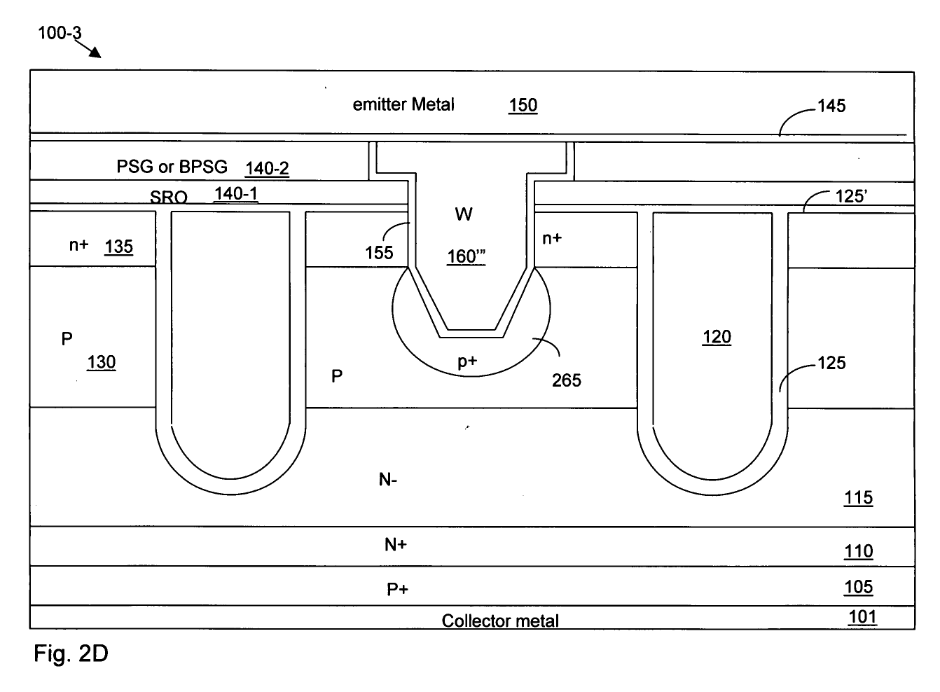

Referring to FIG. 2A for a side cross sectional view of an insulated gate bipolar transistor (IGBT) device 100 formed as a vertical power device on a P+ semiconductor substrate 105. The IGBT device is a punch-through (PT) type of IGBT device. The P+ substrate 105 functions as a collector region with a collector metal 101 formed on the bottom surface. The P+ substrate 105 supports N+ and N− epitaxial layers 110 and 115 grown on top of the P+ substrate 105 for functioning as a buffer layer and N-base layer respectively. The IGBT device further comprises trench gates 120 filled with gate dielectric layer such as polysilicon and padded with gate oxide layer 125. The trench gates are surrounded by P-base regions 130 that encompass N+ emitter regions 135 formed near the top surface of the substrate. The top surface of the substrate is covered with an insulation layer 140 on overlaying the insulation layer 125′ formed together with the gate insulation layer 125.

The IGBT device further comprises emitter-base contact trenches opened through the insulation layer 140 and padded with a barrier layer 155 composed of Ti/TiN or Co/TiN filled with tungsten contact plugs 160 filling in the contact trenches for contacting the emitter regions 135 and the base region 130. Each of these emitter-base contact trenches further are extended into the P-base regions 130 having a P+ dopant region 165 implanted below the contact trenches to reduce the contact resistance and enhance the electrical contact to the emitter-base regions. The top surface of the insulation layer 140 may be covered with a resistance-reduction layer 145 composed of Ti or Ti/TiN for expanding the contact area between the emitter metal 150 to the emitter-base trench contact 160 to reduce the contact resistance.

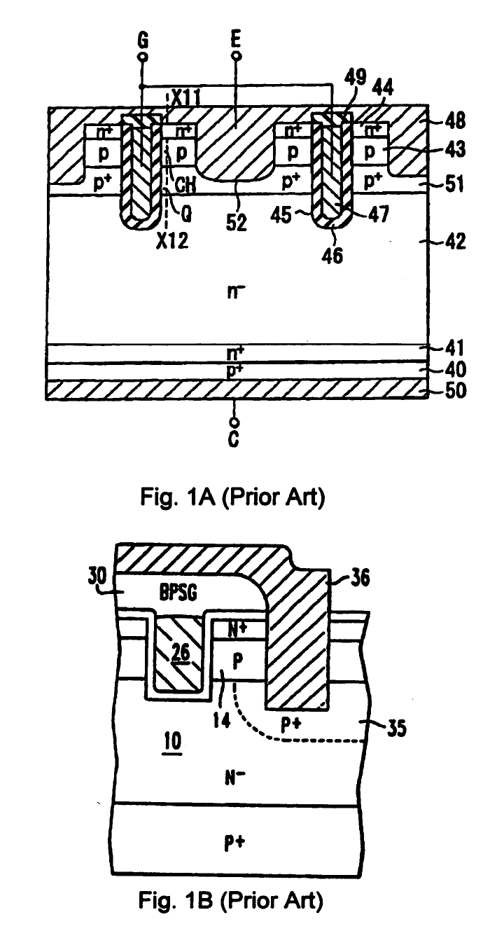

The heavily doped P+ regions 165 are formed around bottom of the contact trenches with a certain distance from channel region to reduce base-emitter resistance to reduce the susceptibility of the IGBT device from latch-up. The reduction of the base-emitter resistance depends on the doping concentration of the P+ dopant regions 165 and distance between emitter-base trench contact 160 to trench gate 120 and also the dopant concentration of the P base regions 130. Please refer FIG. 2A-1 for an equivalent circuit of IGBT which is a combination of a MOSFET and thyristor that comprises an NPN and a PNP transistors. The resistor Rb represents the resistance between base and emitter. If the current flows through the Rb and make voltage drop across the Rb resistor equal to 0.7V, the thyristor is triggered on, then the IGBT can not be turned off which is referred to as “latch-up”. The latch-up phenomena may cause an over-current to destroy the device. The heavily doped P+ regions 165 around the bottom of the contact trenches is formed at certain optimum distance around 0.2 μm from channel region, where the optimum distance is defined by root square of [(contact width tolerance)²+(trench width tolerance)²+(misalignment tolerance between contact to trench)²] to ensure that P+ base regions will be very close to channel region but never touch to channel region during manufacturing to enhance latch-up immunity capability. The IGBT of this invention is formed without requiring to trade-off between the gate-emitter threshold voltage and latch-up immunity capability. The disadvantage of the conventional configuration with the P+ base regions touching the channel regions thus resulting higher gate-emitter threshold voltage is therefore prevented.

FIG. 2B shows a similar embodiment of an IGBT 100-1 as the IGBT device of FIG. 2A. The trench emitter-base contacts 160′ include tungsten contact plugs filling in the contact trenches formed with sloped sidewalls with tapered angle less than 85 degrees with respect to flat bottom portion of the emitter-base contact trenches within the P-base regions. The sloped sidewalls provide better contact to the P+ region 165 along the sidewalls of the contact trenches 160′. The P+ region 165 are formed by implantation through the sloped sidewalls instead of implanting the dopant ions through the bottom surface of the contact trenches followed by diffusion operation to expand the P+ region to the regions surrounding the sidewalls. A more uniform distribution of the dopant ions around the sidewalls of the contact trench 160′ reduces the base resistance from the channel region to the emitter. The reduced based resistance further leads to improvements of the latch-up immunity or short-circuit capability. The tapered angle is less than 85 degrees with respect to flat bottom portion of the emitter-base contact trenches within the P-base regions. With increased contact areas to the P+ regions, the base resistance is reduced thus further decreases the susceptibility of the IGBT device from latch-up. The slopped sidewalls of the emitter-base contact trenches may be processed by adjusting the dry etch chemistry, pressure and power in the etching process in opening the emitter-base contact trenches.

FIG. 2C shows another similar embodiment of an IGBT 100-2 as the IGBT device of FIG. 2A. The trench emitter-base contacts 160″ include polygon-shaped tungsten contact plugs 160″, i.e., substantially W-shaped plugs, filling in the contact trenches formed with vertical sidewalls in n+ emitter region and the bottom portion of the sidewalls in P-base region formed with as sloped sidewalls converging to a flat trench bottom. The contact trenches in FIG. 2C have vertical sidewalls in n+emitter region 135 and slope shape with tapered angle less than 85 degrees with respect to flat bottom portion of the emitter-base contact trenches within the P-base regions 130. The sloped sidewalls near the bottom potion provides better contact to the P+ base contact region 165 because the P+ doped region 165 can be directly implanted by applying a zero degree P+ dopant implant through the slope sidewalls to achieve more uniform dopant distribution near the sidewalls. The P+ base contact region 165 is implanted without dopant concentration reduction near some parts of the sidewalls when the P+ base contact region 165 is formed by applying a diffusion process. Better emitter contact resistance is therefore achieved. During a process of applying a zero degree P+ ion implantation with energy ranging from 20 KeV to 100 KeV into contact trenches, there are no P+ dopant ions implanted into the regions surrounding the vertical sidewalls of contact trenches in n+ emitter region 135. The P+ dopant ions are however implanted into the regions under the slope shape sidewalls and below the bottom surface of contact trenches in P-base region 130. Therefore, this embodiment of contact trenches with bottom sloped sidewalls provide a prefer configuration of the present invention. The sidewalls with tapered angle are less than 85 degrees with respect to flat bottom portion of the emitter-base contact trenches within the P-base regions, the range of implant energy from 20˜100 KeV, type of ions such as boron and BF2 are commonly used for P+ ion Implantation.

FIG. 2D shows another similar embodiment of an IGBT 100-3 as the IGBT device of FIG. 2C. The trench emitter-base contacts 160′″ include polygon-shaped tungsten contact plugs 160″, i.e., substantially W-shaped plugs, filling in the contact trenches formed with the bottom portion of the sidewalls formed with as sloped sidewalls converging to a flat trench bottom. This IGBT device has a similar configuration as the IGBT device 100-2 shown in FIG. 2C except the emitter-contact trenches have a wider top opening. The tungsten plug filling in the emitter-base contact trenches now has a wider top surface than the tungsten plug filling in the portion of the trenches in the emitter regions thus providing better interface with the emitter metal. Because the top surface area of the emitter contact plugs have wider top surface, the contact plugs provide more contact area with the emitter metal for further reducing the contact resistance.

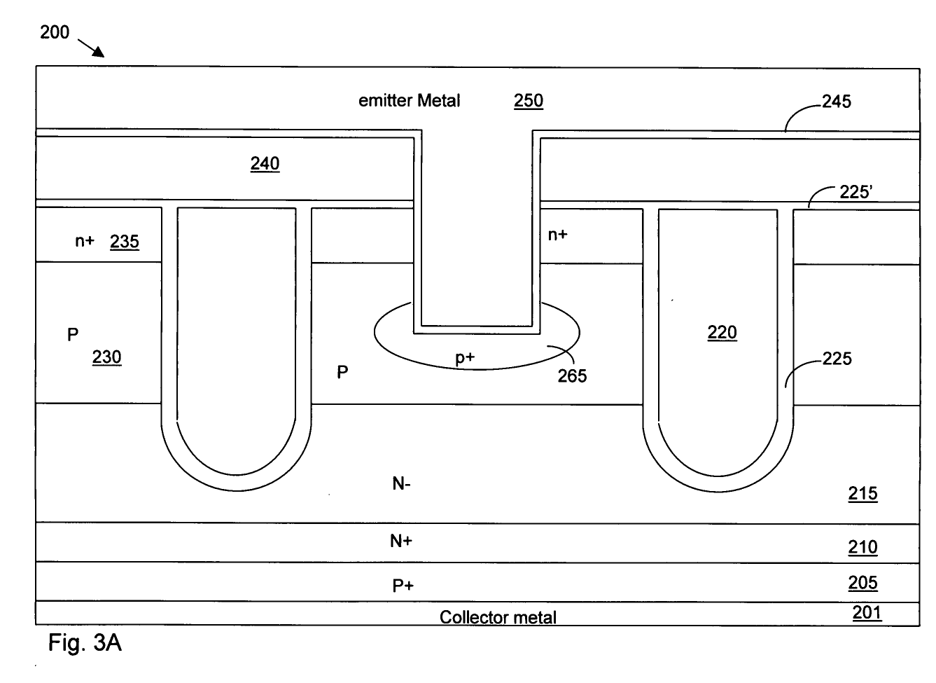

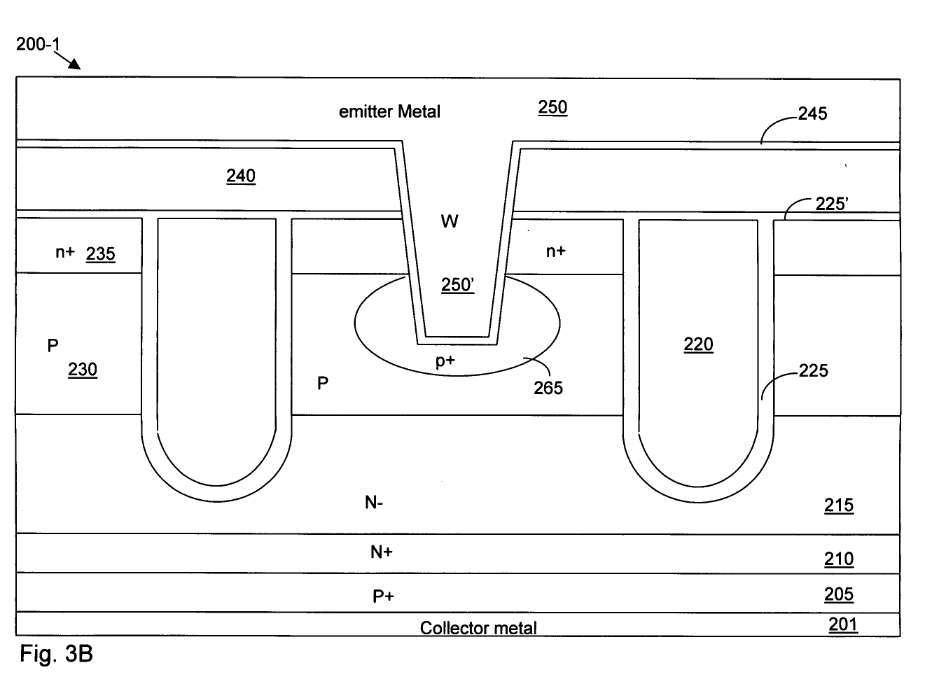

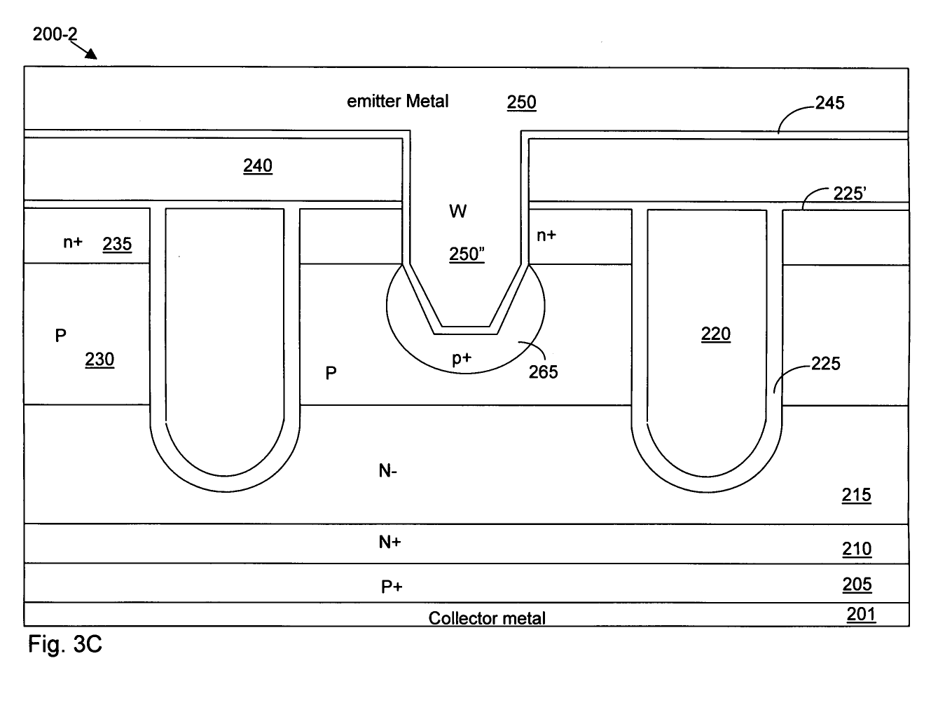

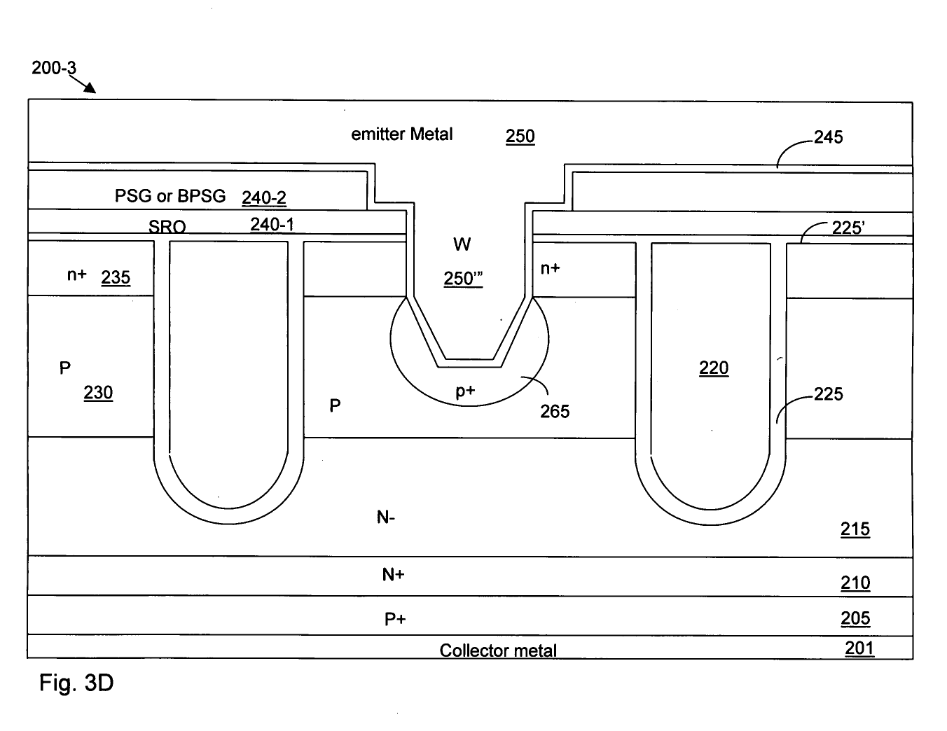

Referring to FIG. 3A for a side cross sectional view of an insulated gate bipolar transistor (IGBT) device 200 formed as a vertical power device on a P+ semiconductor substrate 205. The IGBT device is a punch-through (PT) type of IGBT device. The P+ substrate 205 functions as a collector region with a collector metal 201 formed on the bottom surface. The P+ substrate 205 supports N+ and N− epitaxial layers 210 and 215 grown on top of the P+ substrate 205 for functioning as a buffer layer and N-base layer respectively. The IGBT device further comprises trench gates 220 filled with gate dielectric layer such as polysilicon and padded with gate oxide layer 225. The trench gates are surrounded by P-base regions 230 that encompass N+ emitter regions 235 formed near the top surface of the substrate. The top surface of the substrate is covered with an insulation layer 240 on overlaying the insulation layer 225′ formed together with the gate insulation layer 225.

The IGBT device 200 further comprises emitter-base contact trenches opened through the insulation layer 240 and padded with a barrier layer 255 composed of Ti/TiN or Co—TiN and filled with emitter metal 250 in the contact trenches for contacting the emitter regions 235 and the base regions 230. Each of these emitter-base contact trenches further are extended into the P-base regions 230 having a P+ dopant region 265 implanted below the contact trenches to reduce the contact resistance and enhance the electrical contact to the emitter-base regions.

The heavily doped P+ regions 265 are formed to enhance the contact for the emitter metal to the emitter and base regions. The disadvantage of the conventional configuration with the P+ base regions touching the channel regions thus resulting higher gate-emitter threshold voltage is therefore prevented.

FIG. 3B shows a similar embodiment of an IGBT 200-1 as the IGBT device of FIG. 3A. The trench emitter-base contacts 250′ include emitter metal filling in the contact trenches formed with sloped sidewalls.

FIG. 3C shows another similar embodiment of an IGBT 200-2 as the IGBT device of FIG. 3A. The trench emitter-base contacts 250″ include polygon-shaped tungsten contact plugs 260″, i.e., substantially W-shaped plugs, filling in the contact trenches formed with the bottom portion of the sidewalls formed with as sloped sidewalls converging to a flat trench bottom.

FIG. 3D shows another similar embodiment of an IGBT 200-3 as the IGBT device of FIG. 3C. The trench emitter-base contacts 250′″ include polygon-shaped tungsten contact plugs 260″, i.e., substantially W-shaped plugs, filling in the contact trenches formed with the bottom portion of the sidewalls formed with as sloped sidewalls converging to a flat trench bottom.

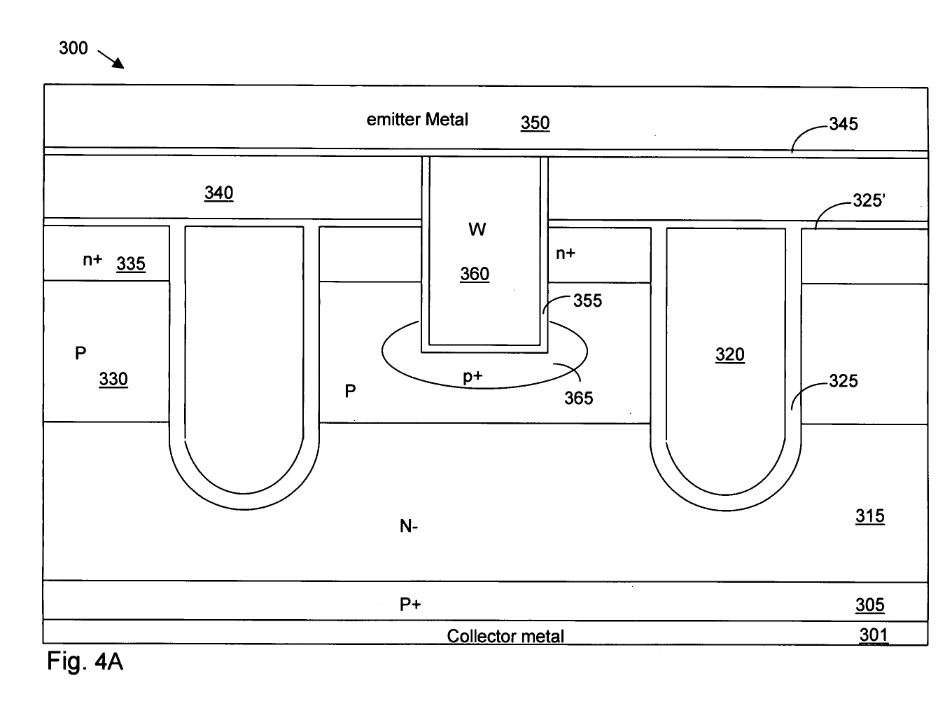

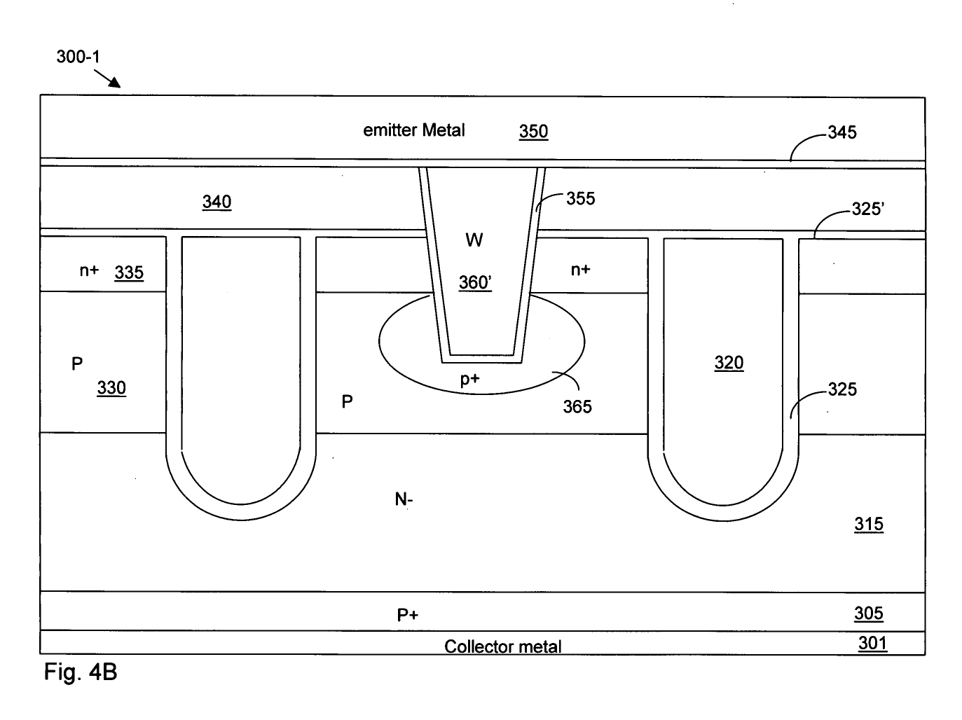

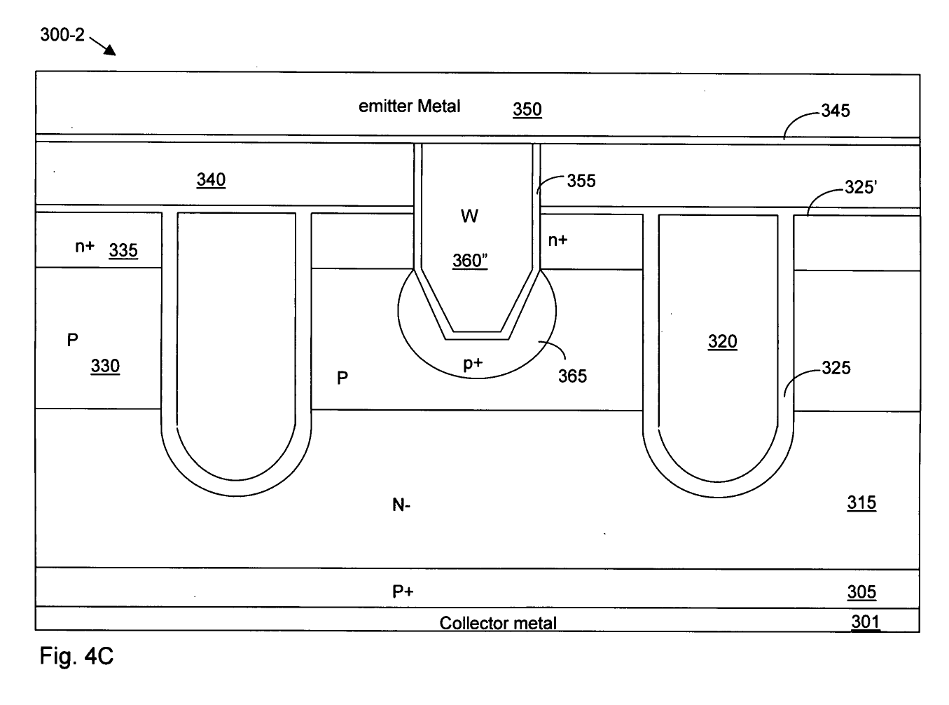

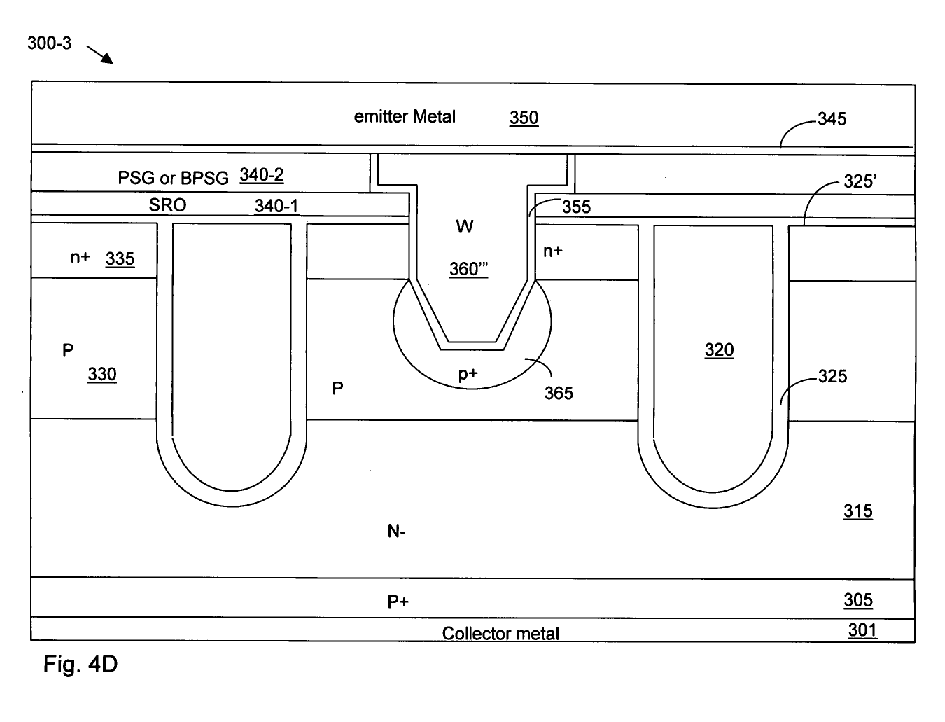

Referring to FIG. 4A for a side cross sectional view of an insulated gate bipolar transistor (IGBT) device 300 formed as a vertical power device on a floating zone (FZ) N− base silicon substrate 315 with a shallow P+ collector 305 formed on backside by ion implantation after backside grinding. The IGBT device is a non-punch-through (NPT) type of IGBT device. The P+ collector 305 functions as a collector region with a collector metal 301 formed on the bottom surface. The IGBT device further comprises trench gates 320 filled with gate dielectric layer such as polysilicon and padded with gate oxide layer 325. The trench gates are surrounded by P-base regions 330 that encompass N+ emitter regions 335 formed near the top surface of the substrate. The top surface of the substrate is covered with an insulation layer 340 on overlaying the insulation layer 325′ formed together with the gate insulation layer 325. The IGBT device further comprises emitter-base contact trenches opened through the insulation layer 340 and padded with a barrier layer 355 composed of Ti/TiN or Co/TiN filled with tungsten contact plugs 360 filling in the contact trenches for contacting the emitter regions 335 and the base region 330. Each of these emitter-base contact trenches further are extended into the P-base regions 330 having a P+ dopant region 365 implanted below the contact trenches to reduce the contact resistance and enhance the electrical contact to the emitter-base regions. The top surface of the insulation layer 340 may be covered with a resistance-reduction layer 345 composed of Ti or Ti/TiN for expanding the contact area between the emitter metal 350 to the emitter-base trench contact 360 to reduce the contact resistance.

The heavily doped P+ regions 365 are formed around bottom of contact trenches with certain distance from channel region to enhance the contact of the emitter metal layer 350 to the emitter regions 335 and the base regions 335. The disadvantage of the conventional configuration with the P+ base regions touching the channel regions thus resulting higher gate-emitter threshold voltage is therefore prevented.

FIG. 4B shows a similar embodiment of an IGBT 300-1 as the IGBT device of FIG. 4A. The trench emitter-base contacts 360′ include tungsten contact plugs filling in the contact trenches formed with sloped sidewalls.

FIG. 4C shows another similar embodiment of an IGBT 300-2 as the IGBT device of FIG. 4A. The trench emitter-base contacts 360″ include polygon-shaped tungsten contact plugs 360″, i.e., substantially W-shaped plugs, filling in the contact trenches formed with vertical sidewalls with an n+ emitter region and the bottom portion of the sidewalls within P-base region formed with as sloped sidewalls converging to a flat trench bottom.

FIG. 4D shows another similar embodiment of an IGBT 300-3 as the IGBT device of FIG. 4C. The trench emitter-base contacts 360′″ include polygon-shaped tungsten contact plugs 360″, i.e., substantially W-shaped plugs, filling in the contact trenches formed with the bottom portion of the sidewalls formed with as sloped sidewalls converging to a flat trench bottom. This embodiment is same as FIG. 4C except the W plug portion interfaced with the emitter metal is wider than that in n+ emitter region, providing more contact area with the emitter metal for further reducing the contact resistance.

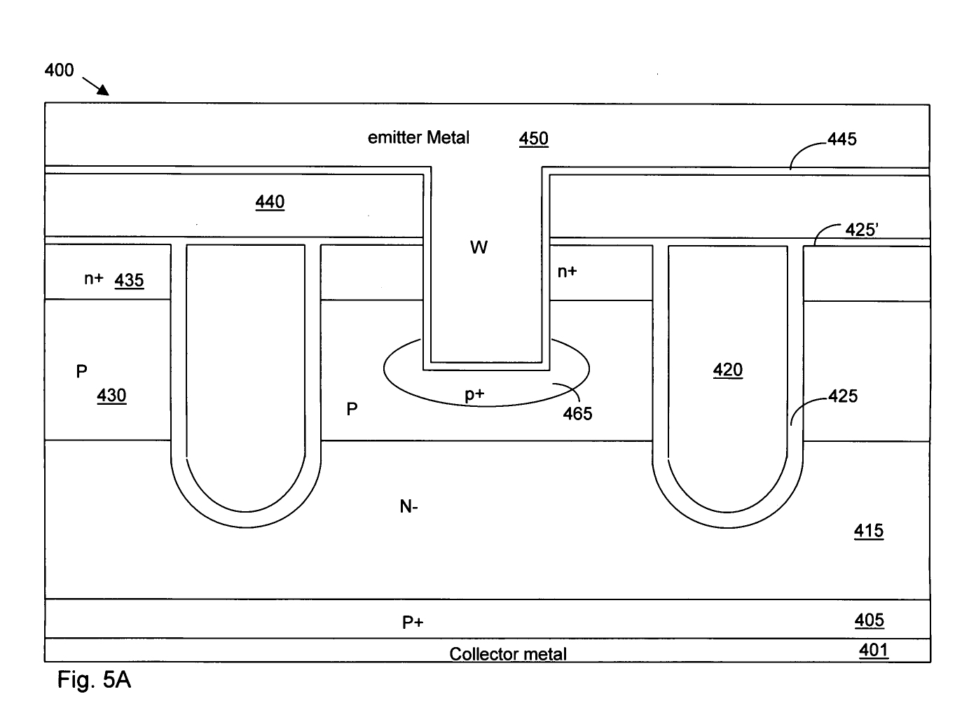

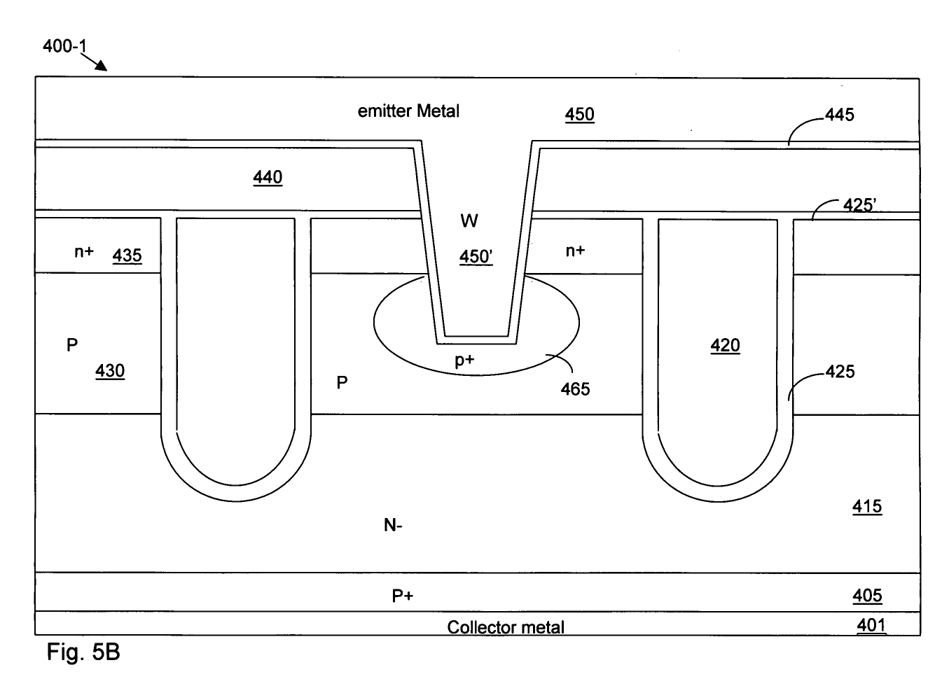

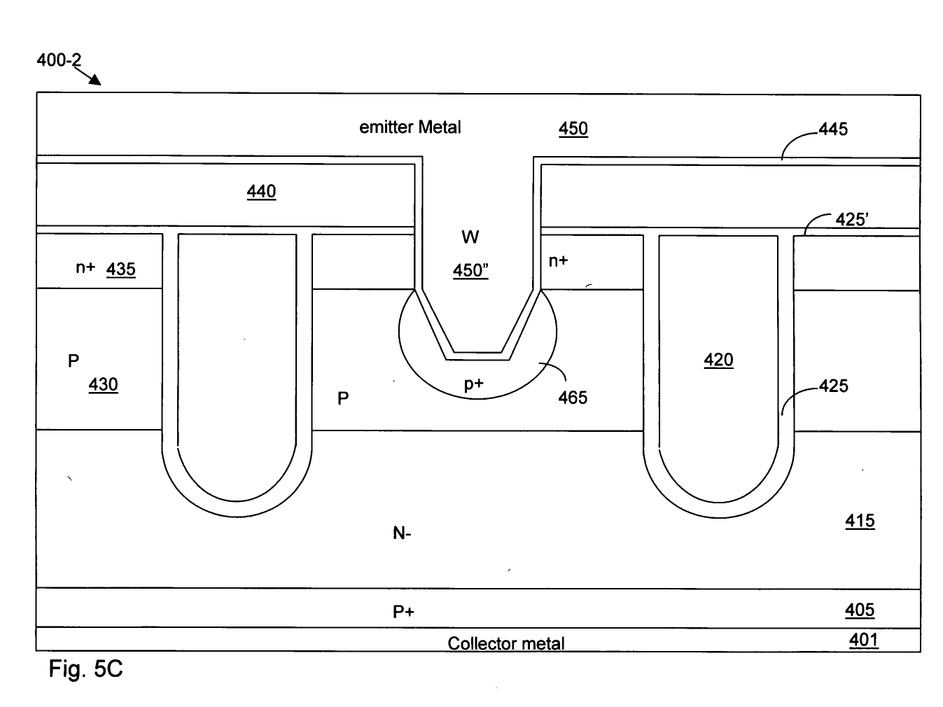

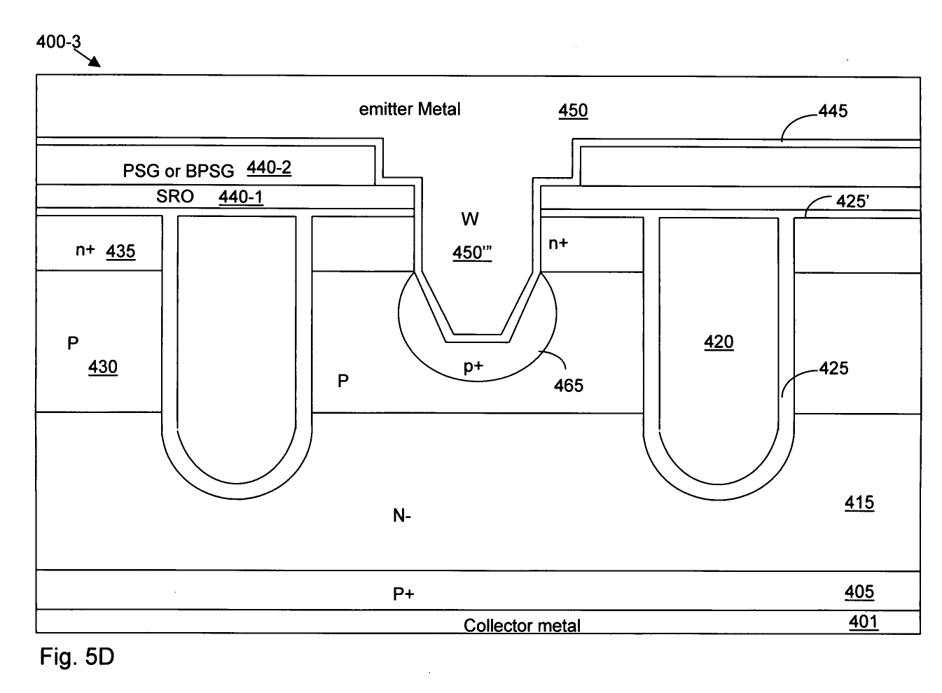

Referring to FIG. 5A for a side cross sectional view of an insulated gate bipolar transistor (IGBT) device 400 formed as a vertical power device on a floating zone (FZ) N− base silicon substrate 415 with a shallow P+ collector 405 formed on backside by ion implantation after backside grinding. The IGBT device is a non-punch-through (NPT) type of IGBT device. The P+ collector 405 functions as a collector region with a collector metal 401 formed on the bottom surface. The IGBT device further comprises trench gates 420 filled with gate dielectric layer such as polysilicon and padded with gate oxide layer 425. The trench gates are surrounded by P-base regions 430 that encompass N+ emitter regions 435 formed near the top surface of the substrate. The top surface of the substrate is covered with an insulation layer 440 on overlaying the insulation layer 425′ formed together with the gate insulation layer 425.

The IGBT device 400 further comprises emitter-base contact trenches opened through the insulation layer 440 and padded with a barrier layer 455 composed of Ti/TiN or Co/TiN and filled with emitter metal 450 in the contact trenches for contacting the emitter regions 435 and the base regions 430. Each of these emitter-base contact trenches further are extended into the P-base regions 430 having a P+ dopant region 465 implanted below the contact trenches to reduce the contact resistance and enhance the electrical contact to the emitter-base regions.

The heavily doped P+ regions 465 are formed to enhance the contact for the emitter metal to the emitter and base regions. The disadvantage of the conventional configuration with the P+ base regions touching the channel regions thus resulting higher gate-emitter threshold voltage is therefore prevented.

FIG. 5B shows a similar embodiment of an IGBT 400-1 as the IGBT device of FIG. 5A. The trench emitter-base contacts 450′ include emitter metal filling in the contact trenches formed with sloped sidewalls.

FIG. 5C shows another similar embodiment of an IGBT 400-2 as the IGBT device of FIG. 5A. The trench emitter-base contacts 450″ include polygon-shaped tungsten contact plugs 460″, i.e., substantially W-shaped plugs, filling in the contact trenches formed with vertical sidewalls within n+ emitter region and the bottom portion of the sidewalls within the P-base region formed with as sloped sidewalls converging to a flat trench bottom.

FIG. 5D shows another similar embodiment of an IGBT 400-3 as the IGBT device of FIG. 5C. The trench emitter-base contacts 450′″ include polygon-shaped tungsten contact plugs 460″, i.e., substantially W-shaped plugs, filling in the contact trenches formed with the bottom portion of the sidewalls formed with as sloped sidewalls converging to a flat trench bottom.

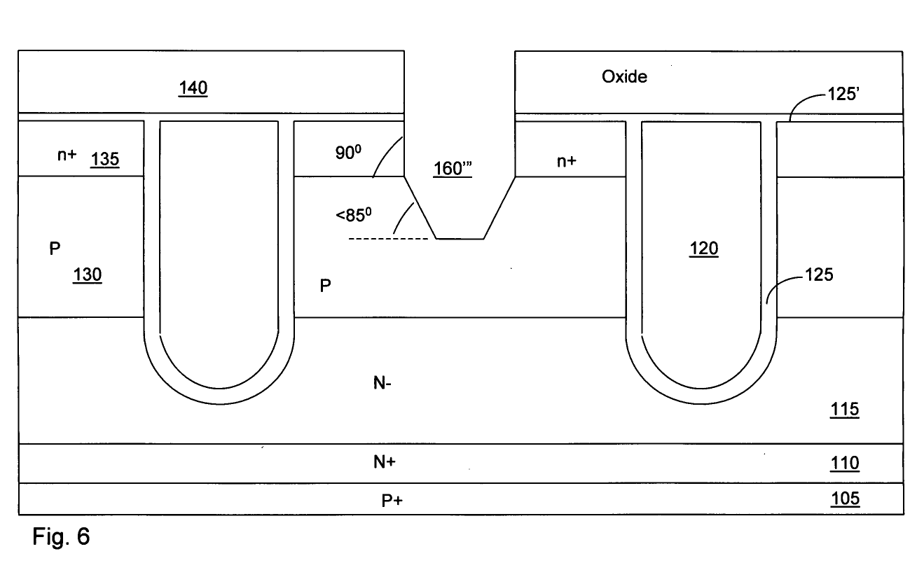

FIG. 6 shows a process of opening a polygon-shaped emitter-base contact trench. The process starts with an application of mask of emitter-base contact trench (not shown) followed by a dry oxide etch to remove the oxide layer 140 to open a trench window. The process proceeds with a dry silicon etch to open the trench 160′″ with substantially vertical sidewall with angular orientation of approximately 90 degrees ±3 degrees within the emitter regions 135. The dry etch further forms sidewalls with tapered angle less than 85 degrees with respect to a flat bottom portion of the emitter-base contact trenches within the P-base regions. Because the etching rate and profile is depending on doping concentration of silicon, a single dry etch recipe is able to be adjusted to meet the profile easily.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

I claim:

1. A trench insulation gate bipolar transistor (IGBT) power device comprising a plurality of trench gates surrounded by emitter regions of a first conductivity type near a top surface of a semiconductor substrate encompassed in base regions of a second conductivity type, said trench semiconductor power device further comprising:
an epitaxial layer of a first conductivity type comprising a layer below said base region of said second conductivity and a buffer layer with a higher concentration of dopant ions of said first conductivity than said base layer of said first conductivity;
a collector layer of said second conductivity type disposed below said buffer layer;
an insulation layer covering over said top surface over said trench gate and said emitter regions having emitter-base contact trenches opened therethrough between said trench gates and extending to said base regions of said second conductivity wherein each of said emitter-base contact trenches filled with a metal plug for electrically contacting said emitter regions and said base regions; and
an emitter-base contact dopant region disposed in said base region of said second conductivity type surrounding a lower region of said contact trenches and doped with a higher concentration of dopant ions of said second conductivity type than said base region of said second conductivity type wherein said emitter-base contact dopant region is disposed at a distance away from a channel near said trench gates for reducing an emitter-base resistance without increasing a gate-emitter threshold voltage.

2. The trench IGBT power device of claim 1 wherein:
said emitter-base contact dopant region having a dopant concentration ranging from 1E18 to 1E20 cm⁻³ higher than a dopant concentration of said base region of said second conductivity type.

3. The trench IGBT power device of claim 1 wherein:
said emitter-base contact dopant region is disposed at a distance of about 0.2 μm from said channel of said IGBT near said trench gates.

4. The trench IGBT power device of claim 1 wherein:
said emitter-base contact trenches further comprising a barrier layer disposed around sidewalls and a bottom surface of said emitter-base contact trenches surrounding said metal plug filling in said emitter-base contact trenches.

5. The trench IGBT power device of claim 1 wherein:
said metal plug filled in said emitter-base contact trenches further comprising a tungsten plug for electrically contacting said emitter regions and said base regions.

6. The trench IGBT power device of claim 1 wherein:
said emitter-base contact trenches further comprising a barrier layer composed of Ti/TiN disposed around sidewalls and a bottom surface of said emitter-base contact trenches surrounding said metal plug filling in said emitter-base contact trenches.

7. The trench IGBT power device of claim 1 wherein:
said emitter-base contact trenches further comprising a barrier layer composed of Co—TiN disposed around sidewalls and a bottom surface of said emitter-base contact trenches surrounding said metal plug filling in said emitter-base contact trenches.

8. The trench IGBT power device of claim 1 wherein:
said first conductivity type is an N-type conductivity type and said second conductivity type is a P-type conductivity type.

9. The trench IGBT power device of claim 1 wherein:
said emitter-base contact trenches further comprising sidewalls having substantially a straight-line cross section profile.

10. The trench IGBT power device of claim 1 wherein:
said emitter-base contact trenches further comprising sidewalls having substantially a straight-line cross section profile along substantially a vertical direction relative to said top surface of said semiconductor substrate.

11. The trench IGBT power device of claim 1 wherein:
said emitter-base contact trenches further comprising sidewalls having substantially a straight-line cross section profile along substantially angularly sloped direction relative to said top surface of said semiconductor substrate.

12. The trench IGBT power device of claim 1 wherein:
said emitter-base contact trenches further comprising sidewalls having a vertical line profile on an upper portion of said contact trenches along substantially a direction perpendicular relation to said top surface of said semiconductor substrate and a slope line profile angularly intersecting with said vertical line profile and converging to a flat bottom surface of said contact trenches on a lower portion of said contact trenches.

13. The trench IGBT power device of claim 1 wherein:
said emitter-base contact trenches further comprising sidewalls having a vertical line profile on an upper portion of said contact trenches along substantially a direction perpendicular relation to said top surface of said semiconductor substrate in said emitter regions and a slope line profile angularly intersecting with said vertical line profile and converging to a flat bottom surface of said contact trenches on a lower portion of said contact trenches in said base region of said second conductivity type.

14. The trench IGBT power device of claim 1 wherein:
said emitter-base contact trenches further comprising an widened top opening in said insulation layer having a width greater than a width between sidewalls of said trenches in said emitter regions for providing a greater top surface area than a cross sectional area of said trenches opened in said emitter region and base region in the semiconductor substrate.

15. The trench IGBT power device of claim 1 further comprising:
an metal layer disposed on top of said insulation layer and filling in said emitter-base contact trenches constituting said metal plug filled in said emitter-base contact trenches for electrically contacting said emitter regions and said base regions.

16. A trench insulation gate bipolar transistor (IGBT) power device comprising a plurality of trench gates surrounded by emitter regions of a first conductivity type near a top surface of a semiconductor substrate encompassed in base regions of a second conductivity type and a collector layer disposed at a bottom surface of said semiconductor substrate, said trench semiconductor power device further comprising:
an insulation layer covering over said top surface over said trench gate and said emitter regions having emitter-base contact trenches opened therethrough between said trench gates and extending to said base regions and an emitter-base contact dopant region disposed in said base region of said second conductivity type surrounding a lower region of said contact trenches wherein said emitter-base contact dopant region is disposed at a distance away from a channel near said trench gates for reducing an emitter-base resistance without increasing a gate-emitter threshold voltage.

17. The trench IGBT power device of claim 16 further comprising:
a base layer of said first conductivity type disposed below said base-region of said second conductivity type and above said collector layer.

18. The trench IGBT power device of claim 16 wherein:
said emitter-base contact dopant region having a dopant concentration ranging from 1E18 to 1E20 cm⁻³ higher than a dopant concentration of said base region of said second conductivity type.

19. The trench IGBT power device of claim 16 wherein:
said emitter-base contact dopant region is disposed at a distance of about 0.2 μm from said channel of said IGBT near said trench gates.

20. The trench IGBT power device of claim 16 wherein:
said emitter-base contact trenches further comprising a barrier layer disposed around sidewalls and a bottom surface of said emitter-base contact trenches surrounding said metal plug filling in said emitter-base contact trenches.

21. The trench IGBT power device of claim 16 wherein:
said metal plug filled in said emitter-base contact trenches further comprising a tungsten plug for electrically contacting said emitter regions and said base regions.

22. The trench IGBT power device of claim 16 wherein:
said emitter-base contact trenches further comprising a barrier layer composed of Ti/TiN disposed around sidewalls and a bottom surface of said emitter-base contact trenches surrounding said metal plug filling in said emitter-base contact trenches.

23. The trench IGBT power device of claim 16 wherein:
said emitter-base contact trenches further comprising a barrier layer composed of Co—TiN disposed around sidewalls and a bottom surface of said emitter-base contact trenches surrounding said metal plug filling in said emitter-base contact trenches.

24. The trench IGBT power device of claim 16 wherein:
said first conductivity type is an N-type conductivity type and said second conductivity type is a P-type conductivity type.

25. The trench IGBT power device of claim 16 wherein:
said emitter-base contact trenches further comprising sidewalls having substantially a straight-line cross section profile.

26. The trench IGBT power device of claim 16 wherein:
said emitter-base contact trenches further comprising sidewalls having substantially a straight-line cross section profile along substantially a vertical direction relative to said top surface of said semiconductor substrate.

27. The trench IGBT power device of claim 16 wherein:
said emitter-base contact trenches further comprising sidewalls having substantially a straight-line cross section profile along substantially angularly sloped direction relative to said top surface of said semiconductor substrate.

28. The trench IGBT power device of claim 16 wherein:
said emitter-base contact trenches further comprising sidewalls having a vertical line profile on an upper portion of said contact trenches along substantially a direction perpendicular relation to said top surface of said semiconductor substrate and a slope line profile angularly intersecting with said vertical line profile and converging to a flat bottom surface of said contact trenches on a lower portion of said contact trenches.

29. The trench IGBT power device of claim 16 wherein:
said emitter-base contact trenches further comprising sidewalls having a vertical line profile on an upper portion of said contact trenches along substantially a direction perpendicular relation to said top surface of said semiconductor substrate in said emitter regions and a slope line profile angularly intersecting with said vertical line profile and converging to a flat bottom surface of said contact trenches on a lower portion of said contact trenches in said base region of said second conductivity type.

30. The trench IGBT power device of claim 16 wherein:
said emitter-base contact trenches further comprising an widened top opening in said insulation layer having a width greater than a width between sidewalls of said trenches in said emitter regions for providing a greater top surface area than a cross sectional area of said trenches opened in said emitter region and base region in the semiconductor substrate. (FIG. 4D).

31. The trench IGBT power device of claim 16 further comprising:
an metal layer disposed on top of said insulation layer and filling in said emitter-base contact trenches constituting said metal plug filled in said emitter-base contact trenches for electrically contacting said emitter regions and said base regions. (FIG. 5A-5D).

32. A method for manufacturing a trench IGBT power device comprising steps of forming trench gate and emitter and base regions in a semiconductor substrate, the method further comprising:
covering a top surface of said semiconductor substrate with an insulation layer and applying a mask to etch and open a plurality of emitter-base contact trenches through said insulation layer into said base region wherein the etch process further comprising a process of applying a single etch process for opening a substantially vertical trench in said emitter region and etching a bottom portion in said base region with a tapered angle with sloped sidewalls merging to a bottom surface of said contact trenches.

33. The method of claim 32 further comprising:
applying a zero degree dopant implant into said emitter-base contact trenches for form an emitter-base contact dopant region in said base region surrounding said bottom portion of said emitter-base contact trenches.
